(19) United States
(12) Patent Application Publication
(10) Pub. No.: US 2009/0045987 A1
(43) Pub. Date: Feb. 19, 2009

(54) METHOD AND APPARATUS FOR ENCODING/DECODING METADATA

(75) Inventors: Kyung-sun Cho, Seoul (KR); Jeong-hoon Park, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/165,842

(22) Filed: Jul. 1, 2008

(30) Foreign Application Priority Data
Aug. 13, 2007 (KR) 10-2007-0081441

(51) Int. Cl. H03M 7/00

(52) U.S. Cl. 341/50

(57) ABSTRACT

A method for encoding metadata having a plurality of symbols is provided. The encoding method includes: determining an indication of a previously encoded symbol having substantially same symbol data as that of a current symbol that is to be encoded and encoding the current symbol based on the previously encoded symbol.

### CROSS-REFERENCE TO RELATED PATENT APPLICATION

This application claims priority from Korean Patent Application No. 10-2007-0081441, filed on Aug. 13, 2007, in the Korean Intellectual Property Office, the disclosure of which is incorporated herein in its entirety by reference.

### BACKGROUND OF THE INVENTION

1. Field of the Invention

Apparatuses and methods consistent with the present invention relate to data encoding and decoding, and more particularly, to a method and apparatus for efficiently encoding/decoding duplicate symbols included in metadata and a recording medium thereof.

2. Description of the Related Art

Advancement in multimedia technologies triggers development of methods of satisfying users' various demands for multimedia contents. Metadata is used to perform a fast and exactly search for desired data among a large amount of multimedia data. The metadata is allocated to content according to predetermined rules, and contains various information, such as the location and the details of the content, the details of a content producer, right conditions, usage conditions, and usage history.

### SUMMARY OF THE INVENTION

The present invention provides methods and apparatuses for efficiently encoding/decoding duplicate data included in metadata.

The present invention also provides a data structure for efficiently transmitting duplicate data included in metadata, and a computer readable medium with a recorded program for executing the above method.

According to an aspect of the present invention, there is provided a method of encoding metadata having a plurality of symbols, the method including: determining an indication of a previously encoded symbol having substantially same symbol data as that of a current symbol that is to be encoded; and encoding the current symbol based on the previously encoded symbol.

The encoding of the current symbol based on the previously encoded symbol may include obtaining location information of the previously encoded symbol, and encoding the location information. The encoding of the current symbol based on the previously encoded symbol may include generating a reference indication identifier indicating that the current symbol is based on the previously encoded symbol, and encoding the reference indication identifier. The symbol data may include parameters. A case where the current symbol and the previously encoded symbol have the same symbol data may include a case where only values of parameters included in the symbol data of the current symbol are different from values of parameters in the previously encoded symbol, and the encoding of the current symbol based on the previously encoded symbol includes encoding the values of the parameters included in the symbol data of the current symbol, which are different from the values of parameters included in the symbol data of the previously encoded symbol. The encoding of the current symbol based on the previously encoded symbol may include generating parameter indication information indicating some of the parameters included in the symbol data of the current symbol whose values are different from the values of the parameters included in the symbol data of the previously encoded symbol; and encoding the parameter indication information.

### BRIEF DESCRIPTION OF THE DRAWINGS

The above and other aspects of the present invention will become more apparent by describing in detail exemplary embodiments thereof with reference to the attached drawings in which:

FIG. 1A illustrates the structures of a symbol according to an exemplary embodiment of the present invention;

FIG. 1B illustrates the structures of a symbol according to an exemplary embodiment of the present invention;

FIG. 2 illustrates a structure of an encoded symbol that has a duplicate of the same symbol data according to an exemplary embodiment of the present invention;

FIG. 3 is a block diagram of a media signal encoding apparatus according to an exemplary embodiment of the present invention;

FIG. 4 is a block diagram of a media signal decoding apparatus according to an exemplary embodiment of the present invention;

FIG. 5 is a flowchart illustrating a metadata encoding method according to an exemplary embodiment of the present invention; and

FIG. 6 is a flowchart illustrating a method of using metadata according to an exemplary embodiment of the present invention.

### DETAILED DESCRIPTION OF EXEMPLARY EMBODIMENTS

Exemplary embodiments of the present invention will now be described in greater detail with reference to the accompanying drawings.

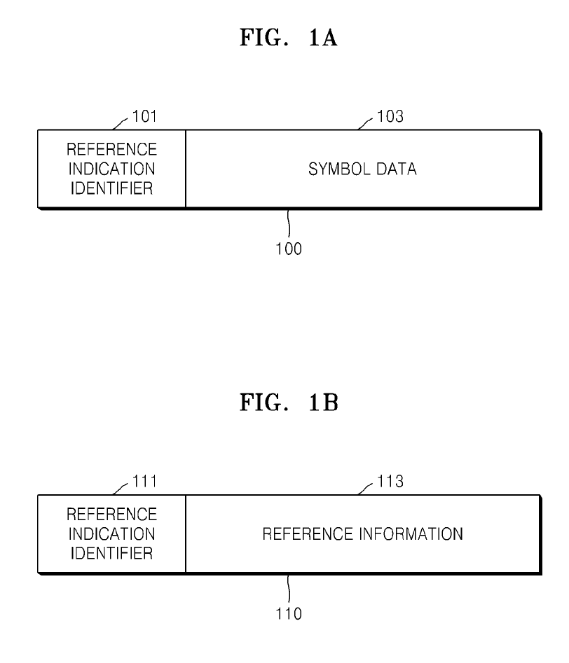

FIGS. 1A and 1B illustrate the structures of a symbol according to exemplary embodiments of the present invention. Referring to FIG. 1A, a symbol 100 includes a reference indication identifier 101 and symbol data 103. Referring to FIG. 1B, a symbol 110 includes a reference indication identifier 111 and reference information 113. Metadata contains a plurality of symbols. A symbol, is code that is defined for processing information regarding a media object or the media object. The symbol may include signs, characters and marks necessary for performing a specific function, and be encoded in a textual or binary format. The reference indication identifier 101 in the symbol 100 indicates whether the symbol 100 has been encoded by referring to another symbol. The reference indication identifier 111 in the symbol 110 indicates whether the symbol 110 has been encoded based on another symbol.

A metadata encoding apparatus encodes metadata in units of symbols. If the same symbol is repeatedly included in the metadata, only the symbol that appears first is encoded. The other duplicate symbols are replaced by encoding only a reference indication identifier indicating that the preceding symbol must be referred to, and reference information specifying the already encoded preceding symbol, thus increasing the efficiency of compression and transmission.

If the symbol 100 that is to be encoded is not based on another symbol, the metadata encoding apparatus encodes the symbol 100 that contains the reference indication identifier 101 indicating that the symbol 100 is not based on another symbol, and the symbol data 103. The symbol data 103 contains various information for object processing, such as signs, characters, and parameters.

If a symbol having the same symbol data as that of a symbol 110 that is to be encoded has already been encoded, the metadata encoding apparatus may encode the symbol 110 based on the already encoded symbol. The metadata encoding apparatus generates the reference indication identifier 111 indicating that the symbol 110 is based on another symbol, and encodes the reference information 113 instead of symbol data such as signs or characters. The reference information 113 may contain location information of another symbol on which the symbol 110 is based. As illustrated in FIG. 1B, the metadata encoding apparatus encodes the symbol 110 that contains the reference indication identifier 111 and the reference information 113.

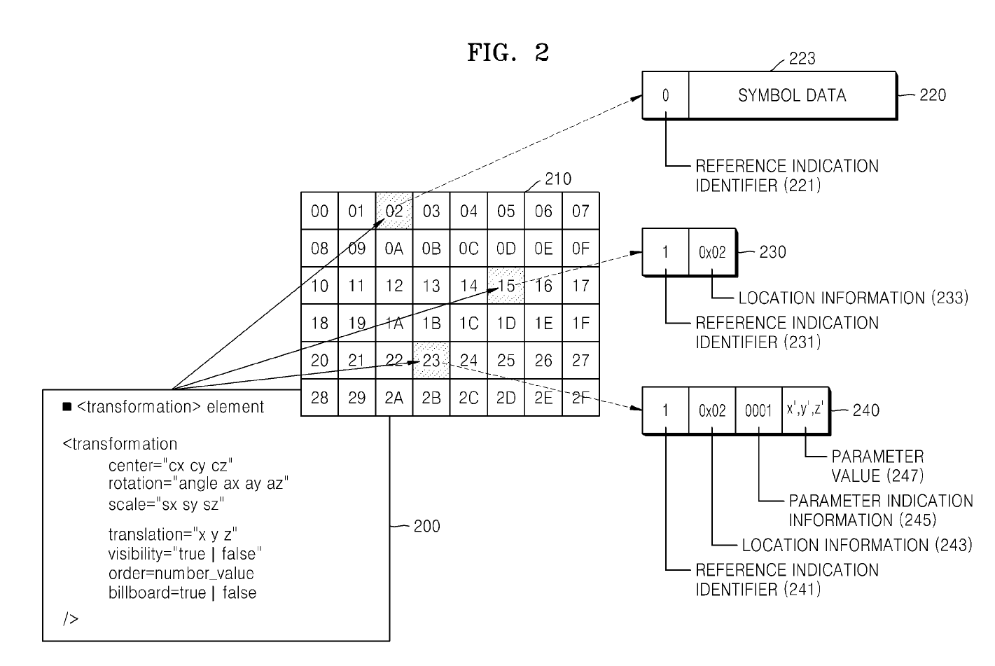

FIG. 2 illustrates the structure of an encoded symbol that has a duplicate of the same symbol data according to an exemplary embodiment of the present invention. Referring to FIG. 2, metadata 210 contains a plurality of symbols. Referring to FIG. 2, the metadata 210 contains a plurality of small squares representing symbols 00 (hexadecimal number) to 2F (hexadecimal number). Although the size or volume of a symbol may vary according to signs included in the symbol or functions of symbol data, FIG. 2 illustrates the symbols in the metadata 210 as same-sized squares, for convenience.

Each of the symbols of the metadata 210 is expressed with a hexadecimal number. A metadata encoding apparatus sequentially encodes the symbols of the metadata 210 from the symbol 00 to the symbol 2F. The metadata 210 may include a duplicate of data having the same symbol. In FIG. 2, it is assumed that symbols 02, 15, and 23 have the same symbol data 200 having a media object transformation attribute. In this case, the encoding apparatus may encode only the symbol data 200 of the symbol 02, which appears first, without encoding all the symbol data 200. Then the symbol data 200 of the symbols 15 and 23, which follow the symbol data 200 of the symbol 02, may be encoded based on the already encoded symbol data 200.

The encoding apparatus determines whether symbols having the same symbol data as that of a current symbol that is to be encoded are encoded. In order to encode the third symbol 02, the encoding apparatus generates a symbol 220 having a reference indication identifier 221 and symbol data 223 having a transformation attribute. Since all symbols having the same symbol data as that of the symbol 02 have not been yet encoded, the encoding apparatus generates the reference indication identifier 221 indicating that the symbol 02 is not based on another symbol, and encodes the symbol data 200 having the transformation attribute in a textual or binary format. The reference indication identifier may be 1-bit information having a value of 0 or 1 to indicate whether the current symbol is based on another symbol.

If there is an encoded previous symbol having the same symbol data as that of a symbol that is to be encoded, the encoding apparatus may generate a symbol based on the previous symbol rather than encoding the symbol data that is to be encoded. In FIG. 2, the symbol data of the symbols 15 and 23 is the same as that of the already encoded symbol 02 and thus symbol structures 230 and 240 may be generated based on the symbol data of the already encoded symbol 02.

In order to encode the symbol 15, the encoding apparatus generates a reference indication identifier 231 indicating that the symbol 15 is based on another symbol. The encoding apparatus obtains location information regarding the symbol 02 on which the symbol 15 is based, and encodes the location information 233 instead of encoding the symbol data 200.

Likewise, in order to encode the symbol 23, the encoding apparatus generates a reference indication identifier 241 indicating that the symbol 23 is based on the symbol 02 that has already been encoded, and obtains location information 243 of the symbol 02 on which the symbol 23 is based.

A case where a current symbol that is to be encoded has substantially the same symbol data as a previous symbol that has already been encoded, except that the current symbol and the previous symbol are different from each other only in terms of the values of parameters included in respective symbol data of the current and previous symbols. Thus, if the values of parameters included in the symbol data of the current symbol are different from those of the symbol data of the previous symbol, the encoding apparatus may encode some of the values of the parameters in the symbol data of the current symbol, which are different from the values of the parameters in the symbol data of the previous symbol. The encoding apparatus may generate information to indicate that some of the parameters in the symbol data of the symbol 23 are different from the parameters in the symbol data of the already encoded symbol 02, or the values of the different parameters.

The symbol data 200 having the transformation attribute includes four groups of parameters, i.e., “cx, cy, cz”, “ax, ay, az”, “sx, sy, sz”, and “x, y, z”. The encoding apparatus may encode parameter indication information indicating parameters in the symbol data of a symbol that is to be encoded, which are different from the parameters in the symbol data of the already encoded symbol that is to be referred.

Referring to FIG. 2, to indicate that a last group of parameters from four groups of parameters included in the symbol data of the symbol 23 is different from a last group of parameters from four groups of parameters included in the symbol data of the symbol 02 to be referred, the encoding apparatus generates parameter indication information 245 whose value is “0001” having a last bit value of “1”, which has a bit-depth corresponding to the total number of the parameter group, that is, which is 4-bit data. The encoding apparatus encodes the last group of parameters values “x′, y′, z” 247 included in the symbol data of the symbol 23. If the symbol 02 having the same symbol data 200 as that of a symbol that is to be encoded has been encoded, the encoding apparatus encodes location information of the encoded symbol 02 having the symbol data 200, rather than encoding the symbol data 200, thereby increasing the efficiency of encoding and transmission.

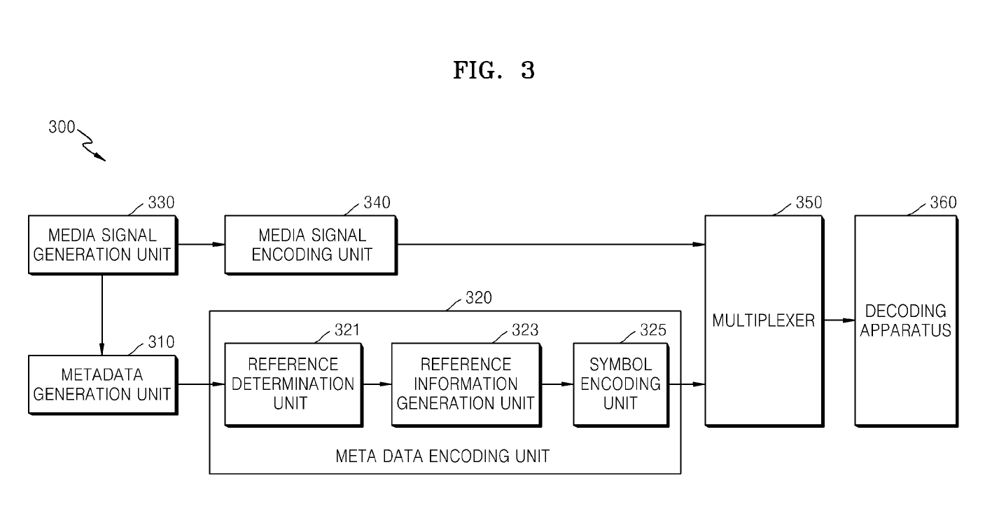

FIG. 3 is a block diagram of a media signal encoding apparatus 300 according to an exemplary embodiment of the present invention. Referring to FIG. 3, the encoding apparatus includes a metadata generation unit 310, a metadata encoding unit 320, a media signal generation unit 330, a media signal encoding unit 340, and a multiplexer 350. In FIG. 3, the metadata encoding unit 320 is illustrated as a part of the encoding apparatus but the present invention is not limited thereto. For example, the metadata encoding unit 320 may process metadata while being separate from the encoding apparatus. The media signal generation unit 330 generates a media signal, such as an audio signal or a video signal. The media signal encoding unit 340 encodes the media signal and transmits the encoded media signal to the multiplexer 350.

The metadata generation unit 310 generates metadata regarding the media signal and transmits the metadata to the metadata encoding unit 320. The metadata may contain various profile information, such as the attributes and manufacturing date of the media signal and information for decoding the media signal. The metadata encoding unit 320 includes a reference determination unit 321, a reference information generation unit 322, and a symbol encoding unit 325. The reference determination unit 321 determines whether symbols having the same symbol data as that of a current symbol to be encoded have been encoded and provides the determination result to the reference information generation unit 323.

If a current symbol that is to be encoded is based on a base or other symbol previously encoded, the reference information generation unit 322 generates reference information regarding the base symbol and transmits the reference information to the symbol encoding unit 325. The reference information may include a unique number or location information of the base symbol. If the current symbol is based on the base symbol, the symbol encoding unit 325 encodes the reference information generated by the reference information generation unit 322. If the current symbol is not based on the base symbol, the symbol encoding unit 325 encodes the reference indication identifier indicating the current symbol is not based on the base symbol, and symbol data of the current symbol. The symbol encoding unit 325 transmits the encoded symbol data or reference information to the multiplexer 350. The multiplexer 350 transmits the encoded symbol data or reference information together with the encoded media signal to a media signal decoding apparatus 360.

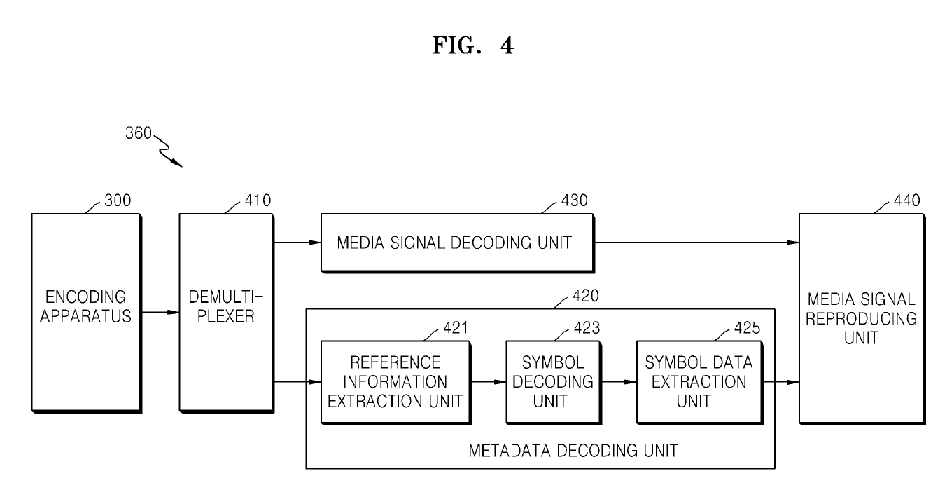

FIG. 4 is a block diagram of a media signal decoding apparatus 360 according to an exemplary embodiment of the present invention. Referring to FIG. 4, the decoding apparatus includes a demultiplexer 410, a metadata decoding unit 420, a media signal decoding unit 430, and a media signal reproducing unit 440. The demultiplexer 410 parses an encoded media signal and encoded metadata received from a media signal encoding apparatus and respectively transmits the media signal and the metadata to the media signal decoding unit 430 and the metadata processor 420. The media signal decoding unit 430 decodes the media signal and transmits the decoded media signal to the media signal reproducing unit 440.

The metadata decoding unit 420 includes a reference information extraction unit 421, a symbol decoding unit 423 and a symbol data extraction unit 425. The metadata decoding unit 420 decodes symbols included in the metadata. The reference information extraction unit 421 determines whether a current symbol that is to be decoded contains reference information, and extracts the reference information based on a determination.

As described above, the reference information may contain location information of a base symbol if the current symbol is based on the base symbol, parameter indication information indicating parameters included in symbol data of the current symbol, which are different from parameters of symbol data of the base symbol, and information indicating the values of the different parameters.

If the current symbol contains a reference indication identifier indicating that the current symbol has been encoded based on a base symbol, the reference information extraction unit 421 extracts the reference information and transmits the reference information to the symbol decoding unit 423. The symbol decoding unit 423 decodes the reference information received from the reference information extraction unit 421 and transmits the decoded reference information to the symbol data extraction unit 425. The symbol data extraction unit 425 identifies the base symbol by using location information of the base symbol. The symbol data extraction unit 425 extracts symbol data of the identified symbol and transmits it to the media signal reproducing unit 440. The media signal reproducing unit 440 reproduces a media signal by using the decoded media signal and the extracted symbol data.

If the current symbol is encoded based on a previous symbol that has already been encoded, symbol data of the previous symbol may be used for decoding the current symbol. Thus, the metadata decoding unit 420 does not need to decode symbol data of the current symbol. Accordingly, it is possible to prevent the same symbol data from being repeatedly decoded, thereby increasing the efficiency of decoding.

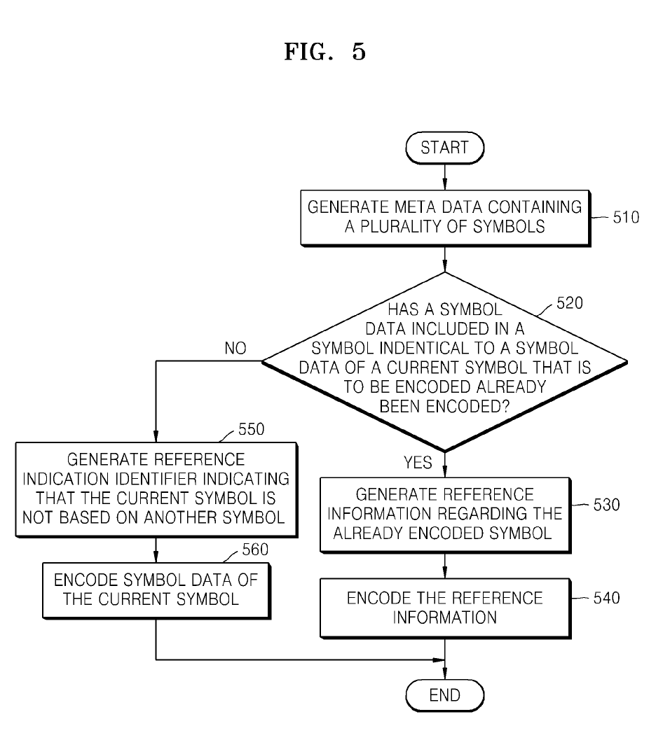

FIG. 5 is a flowchart illustrating a method of encoding metadata according to an exemplary embodiment of the present invention. Referring to FIGS. 3 and 5, the metadata generation unit 310 generates metadata containing a plurality of symbols (operation 510). The symbols included in the metadata are used in order to reproduce a specific media signal. Next, the metadata encoding unit 320 determines whether symbol data identical to symbol data of a current symbol has been encoded (operation 520). If the symbol data identical to the symbol data of the current symbol has already been encoded, the metadata encoding unit 320 generates reference information regarding the already encoded symbol (operation 530) and encodes the reference information (operation 540).

If the symbol data identical to the symbol data of the current symbol is not encoded, the metadata encoding unit 320 generates reference indication identifier indicating that the current symbol is not based on another symbol (operation 550) and encodes symbol data of the current symbol (operation 560). The metadata encoding unit 320 transmits the encoded symbol data or reference information with or separately from the media signal to a media signal decoding apparatus.

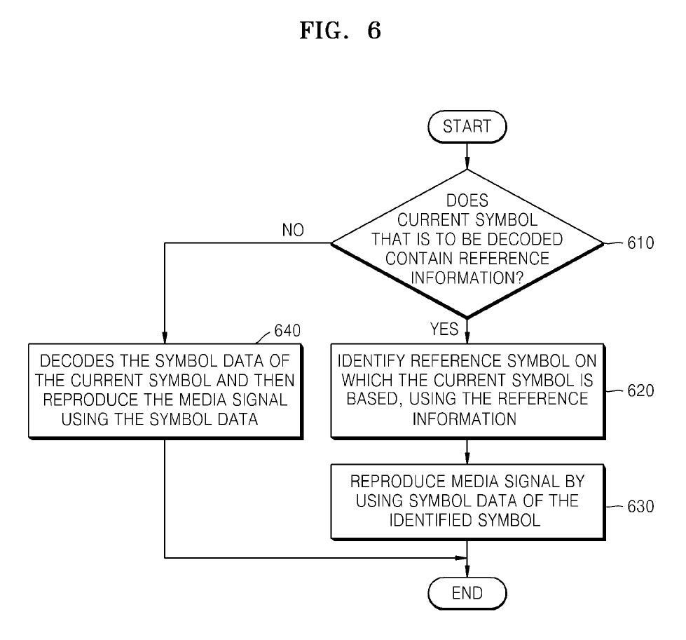

FIG. 6 is a flowchart illustrating a method of using metadata according to an exemplary embodiment of the present invention. Referring to FIGS. 4 and 6, the metadata decoding unit 420 determines whether a current symbol contains reference information (operation 610). If the current symbol contains reference information, the metadata decoding unit 420 identifies a reference symbol on which the current symbol is based, using the reference information (operation 620). As described above, the reference information contains location information or a unique number of a symbol on which the current symbol is based. Thus, the metadata decoding unit 420 may identify the reference symbol using the location information or the unique number. The metadata decoding unit 420 may reproduce a media signal by using symbol data of the reference symbol (operation 630). If the values of some of parameters included in the current symbol are different from the values of parameters included in the reference symbol, the metadata decoding unit 420 may decode the values of the different parameters in the current symbol, and substitute the values of the decoded parameters of the reference symbol. If the current symbol contains the reference information, the metadata decoding unit 420 decodes symbol data included in the current symbol. If the current symbol does not contain the reference information, the metadata decoding unit 420 decodes the symbol data in the current symbol and reproduces the media signal using the symbol data (operation 640).

As described above, the present invention provides a method and apparatus for efficiently encoding/decoding duplicate data included in metadata.

The present invention also provides a data structure for efficiently transmitting duplicate data included in metadata, and a computer readable medium having recorded thereon a program or instructions for executing the above method.

While the present invention has been particularly shown and described with reference to exemplary embodiments, it will be understood by those of ordinary skill in the art that various changes in form and details may be made therein without departing from the spirit and scope of the present invention as defined by the following claims.

What is claimed is:

1. A method of encoding metadata having a plurality of symbols, the method comprising:
determining an indication of a previously encoded symbol having substantially same symbol data as that of a current symbol that is to be encoded; and
encoding the current symbol based on the previously encoded symbol.

2. The method of claim 1, wherein the encoding of the current symbol comprises:
obtaining location information of the previously encoded symbol; and
encoding the location information.

3. The method of claim 1, wherein the encoding of the current symbol comprises:
generating a reference indication identifier indicating that the current symbol is based on the previously encoded symbol; and
encoding the reference indication identifier.

4. The method of claim 1, wherein the symbol data comprises parameters.

5. The method of claim 4, wherein the current symbol and the previously encoded symbol have the same symbol data except for values of parameters, and wherein the encoding of the current symbol comprises:
encoding the values of the parameters of the current symbol that are different from the values of parameters of the previously encoded symbol.

6. The method of claim 5, further comprising:
generating parameter indication information indicating the parameters of the current symbol whose values are different from the values of the parameters included in the symbol data of the previously encoded symbol; and
encoding the parameter indication information.

7. A method of decoding metadata having a plurality of symbols, the method comprising:
identifying in a current symbol to be decoded a reference indication identifier indicating that the current symbol is based on a previous symbol that has already been decoded; and
decoding the current symbol based on the previous symbol.

8. The method of claim 7, wherein the decoding of the current symbol comprises:
extracting location information of the previous symbol from the current symbol; and
decoding the current symbol by using the previous symbol based on the extracted location information.

9. The method of claim 7, wherein the current symbol and the previous symbol comprises symbol data comprising parameters.

10. The method of claim 9, wherein values of some of parameters of the current symbol are different from values of parameters of the previous symbol, and further comprising:
decoding the values of the parameters of the current symbol whose values are different from the values of the parameters of the previous symbol.

11. The method of claim 10, further comprising:
prior to the decoding the values of the parameters, determining the parameters of the current symbol whose values are different from the values of the parameters of the previous symbol.

12. The method of claim 11, further comprising:
performing the decoding by substituting the values of the parameters in the symbol data of the previous symbol with the decoded different values of corresponding parameters of the current symbol.

13. A method of decoding metadata having a plurality of symbols, the method comprising:
decoding the metadata; and
reproducing a media signal by using the decoded metadata, comprising:
reproducing the media signal by using a previous symbol that has already been decoded if a current symbol that is to be decoded comprises a reference indication identifier indicating that the current symbol is based on the previous symbol.

14. An apparatus for encoding metadata having a plurality of symbols, the apparatus comprising:
a reference determination unit which determines whether a current symbol that is to be encoded is encoded based on a previous symbol that has already been encoded;
a reference information generation unit which generates a reference indication identifier indicating that the current symbol is based on the previous symbol, and reference information regarding the previous symbol; and
a symbol encoding unit which encodes the reference information if the current symbol is based on the previous symbol, and encodes the current symbol if the current symbol is not based on the previous symbol.

15. The apparatus of claim 14, wherein the current and previous symbols comprise parameters, and
the reference information generation unit encodes values of the parameters of the current symbol whose values are different from values of the parameters of the previous symbol.

16. An apparatus for decoding metadata, the apparatus comprising:
a reference information extraction unit which extracts a reference indication identifier indicating that a current symbol is based on a previous symbol that has already been decoded, wherein the reference indication identifier is included in the current symbol; and
a symbol decoding unit which decodes the current symbol based on the previous symbol by using the extracted reference indication identifier.

17. The apparatus of claim 16, wherein the reference information extraction unit further extracts location information of the previous symbol from the current symbol, and
the symbol decoding unit decodes the current symbol based on the previous symbol based on the extracted location information.

18. The apparatus of claim 16, wherein the current and previous symbols comprise parameters, and wherein:
if values of some of the parameters of the current symbol are different from values of the parameters of the previous symbol, the reference information extraction unit further extracts the parameters whose values are different, and
the symbol decoding unit decodes the extracted different values of the parameters and substitutes the decoded different values of the parameters into corresponding parameters in the previous symbol.

19. A computer readable medium having recorded thereon a program for executing a metadata encoding method, the method comprising:
instructions for encoding a current symbol if the current symbol is not substantially identical to an already encoded symbol; and
instructions for encoding the current symbol based on the already encoded symbol if the current symbol is substantially identical to the already encoded symbol.

20. A computer readable medium having recorded thereon a program for executing a metadata decoding method, the method comprising:
decoding a current symbol, based on an already decoded symbol if the current symbol contains a reference indication identifier indicating that the current symbol is based on the already decoded symbol.
